(19) United States
(12) Patent Application Publication
(10) Pub. No.: US 2016/0004032 A1
(43) Pub. Date: Jan. 7, 2016

(54) SHAPE MEMORY ALLOY APPARATUS AND METHODS OF FORMATION AND OPERATION THEREOF

(71) Applicant: EMPIRE TECHNOLOGY DEVELOPMENT LLC, Wilmington,, DE (US)

(72) Inventors: Christopher A. WIKLOF, Everett, WA (US); Mordehai MARGALIT, Zichron Yaaqov (IL); Takahisa KUSUURA, Kanagawa (JP); Bradley Kirk ROBERTS, Seattle, WA (US)

(21) Appl. No.: 14/769,778

(22) PCT Filed: Feb. 21, 2013
(86) PCT No.: PCT/US13/27084

§ 371 Date: Aug. 21, 2015

(51) Int. Cl. G02B 7/18; G02B 5/10; H01L 35/32; G02B 5/08

(52) U.S. Cl. CPC G02B 7/181; G02B 5/0833; G02B 5/10; H01L 35/32

(57) ABSTRACT

An optical component is disclosed, as well as articles of manufacture, methods for forming, and methods of operating thereof. The optical component may include a plurality of patterned two-way shape memory alloy portions. Each patterned two-way shape memory alloy portion may include a reflective surface and a temperature adjustment element. Each patterned two-way shape memory alloy portion may be individually configured to flex to a first bend angle at a first temperature and a second bend angle at a second temperature.

### BACKGROUND

Imaging devices, such as cameras and the like, commonly use a multiple lens apparatus that has a plurality of solid transparent lenses that require one or more mechanical components to arrange each lens in a manner that results in proper light reflection to obtain a focused image. The one or more mechanical components are frequently subject to failure, damage, inappropriate operation, and/or the like. Additionally, in some instances, the multiple lens apparatus can be large, heavy and generally cumbersome to use.

### SUMMARY

In an embodiment, an optical component may include a plurality of patterned two-way shape memory alloy portions. Each patterned two-way shape memory alloy portion may include a reflective surface and a temperature adjustment element. Each patterned two-way shape memory alloy portion is individually configured to flex to a first bend angle at a first temperature and a second bend angle at a second temperature.

In an embodiment, an article of manufacture may include an optical component. The optical component may include a plurality of patterned two-way shape memory alloy portions. Each patterned two-way shape memory alloy portion may include a reflective surface and a temperature adjustment element and may be individually configured to flex to a first bend angle at a first temperature and a second bend angle at a second temperature.

In an embodiment, a method of forming an optical element may include forming a two-way shape memory alloy pattern on a substrate, applying a polymer solution to the two-way shape memory alloy pattern to obtain a polymer film, removing the polymer film from the substrate to obtain a polymer compound that may have the polymer solution and the two-way shape memory alloy pattern, molding the polymer compound, depositing a reflective layer upon a surface of the polymer compound, and affixing a temperature adjustment element to the polymer compound.

In an embodiment, a method of operating a shape memory alloy optical element may include determining, by a processor, an object upon which to focus, calculating, by the processor, one or more flex angles for each of a plurality of portions of the shape memory alloy optical element, and based upon the calculating, causing, by the processor, each of the plurality of portions to flex to a calculated flex angle.

### BRIEF DESCRIPTION OF THE DRAWINGS

FIG. 1 depicts a perspective view of a shape memory alloy optical element according to an embodiment.

FIG. 2 depicts a cross-sectional view of a shape memory alloy optical element according to an embodiment.

FIG. 3 depicts a detailed cross-sectional view of a temperature adjustment element according on an embodiment.

FIG. 4A depicts a cross-sectional view of an alternative shape memory alloy optical element according to an embodiment.

FIG. 4B depicts a cross sectional view of an alternative shape memory alloy with varying bend angles according to an embodiment.

FIGS. 5A, 5B, and 5C depict schematic diagrams of using a shape memory alloy optical element or portions thereof to reflect light according to an embodiment.

FIG. 6 depicts a flow diagram of a method for assembling a shape memory alloy optical element according to an embodiment.

FIG. 7 depicts a schematic diagram of an apparatus for training a two way shape memory alloy according to an embodiment.

FIG. 8 depicts a graphical representation of a schematic thermal transformation hysteresis loop according to an embodiment.

FIG. 9 depicts a schematic diagram of assembling a shape memory alloy optical element according to an embodiment.

FIG. 10 depicts illustrative components for an electronic device according to an embodiment.

FIG. 11 depicts a graphical representation of reflectance and wavelength for a plurality of illustrative reflective surfaces according to an embodiment.

### DETAILED DESCRIPTION

This disclosure is not limited to the particular systems, devices, and methods described, as these may vary. The terminology used in the description is for the purpose of describing the particular versions or embodiments only, and is not intended to limit the scope.

As used in this document, the singular forms “a,” “an,” and “the” include plural references unless the context clearly dictates otherwise. Unless defined otherwise, all technical and scientific terms used herein have the same meanings as commonly understood by one of ordinary skill in the art. Nothing in this disclosure is to be construed as an admission that the embodiments described in this disclosure are not entitled to antedate such disclosure by virtue of prior invention. As used in this document, the term “comprising” means “including, but not limited to.”

The following terms shall have, for the purposes of this application, the respective meanings set forth below.

An “imaging device” refers to a device that generally provides imaging capabilities to a user. The imaging device can have an optical element that can be manipulated to zoom in or out on an object, adjust the focus, and/or complete other similar imaging tasks. Examples of imaging devices are not limited by this disclosure and may include, for example, a digital camera, a film camera, a video camera, an infrared imaging device, a gamma imaging device, a single-lens reflex (SLR) camera, a SLR camera lens, a handheld imaging device, a vehicle-mounted imaging device, a barcode scanner, an optical scanner, a telescope, a microscope, a pair of binoculars, a thermal imaging device, a magnifying glass, a contact lens, an intracapsular implant device, eyeglasses, sunglasses, a lighthouse, and the like.

An “electronic device” refers to a device that generally contains at least an imaging device and/or portions thereof. In some embodiments, the electronic device may be an imaging device. In other embodiments, the electronic device may incorporate an imaging device. In some embodiments, the electronic device includes a processor and a tangible, non-transitory, computer-readable memory. The memory may contain programming instructions that, when executed by the processor, cause the computing device to perform one or more operations according to the programming instructions. Examples of electronic devices are not limited by this disclosure, and may include, for example, a television, a computer monitor, a display monitor, a billboard display, a cellular phone, a feature phone, a smartphone, a pager, a personal digital assistant (PDA), a camera, a tablet, a phone-tablet hybrid (for example, a “phablet”), a laptop computer, a netbook, an ultrabook, a global positioning satellite (GPS) navigation device, an automotive component, a media player, a watch, a personal medical device, an electronic photo frame, a security device, a head mounted display, an optical system, a flashlight, aeronautical equipment, automotive equipment, a computer peripheral, a projector, and an optical disc drive, and the like.

The present disclosure relates generally to optical elements for imaging devices and the like. The optical elements described herein may generally contain an ability to zoom, focus, and/or complete other similar tasks. The optical element may provide an advantage over other optical elements known in the art because of their ability to zoom, focus, and/or complete other similar tasks without the need for a user to mechanically manipulate the optical element.

FIG. 1 depicts a perspective view of a shape memory alloy optical element, generally designated 100, according to an embodiment. The shape memory alloy optical element 100 may have at least a plurality of reflective surfaces 105 and a plurality of portions with 2-way shape memory 110. The number of reflective surfaces 105 and portions with 2-way shape memory 110 are not limited by this disclosure, and any number can be used. The number of portions used herein is merely for illustrative purposes only.

While the shape memory alloy optical element 100 described herein is depicted as being substantially circular in shape, those skilled in the art will recognize that any shape may be used without departing from the present scope. In some embodiments, the shape memory alloy optical element 100 may be regular in shape. In other embodiments, the shape memory alloy optical element 100 may be irregular in shape. Examples of shapes may include, but are not limited to, a square, a rectangle, a triangle, a hexagon, a generally round shape, an oval shape, and/or the like.

In various embodiments, the shape memory alloy optical element 100 or any component thereof may have a size. The size of the shape memory alloy optical element 100, as well as any component thereof, is not limited in size by the present disclosure. In some embodiments, the shape memory alloy optical element 100 may have an overall length of about 5 mm to about 50 meters, an overall width of about 5 mm to about 50 meters and an overall depth of about 5 mm to about 50 meters.

In various embodiments, the reflective surface 105 may be any reflective surface now known or later developed, particularly surfaces that may be suitable for imaging purposes. In some embodiments, the reflective surface 105 may include, for example, a substrate and/or a thin layer of high reflectance materials. In some embodiments, the high reflectance materials may include chromium, silver, aluminum, gold, and/or the like. In other embodiments, the reflective surface 105 may be a dielectric mirror. In these embodiments, the dielectric mirror may have a plurality of dielectric material layers. In some embodiments, the dielectric material layers may be thin resin films. In particular embodiments, the dielectric material layers may be thin resin films having various types of nanoparticles. Illustrative nanoparticles may include, for example, one or more of magnesium fluoride, silicon dioxide, tantalum pentoxide, zinc sulfide, and titanium dioxide. In some embodiments, the dielectric material layers may be fabricated by casting, layering, nanoparticle dispersion and/or the like. In some embodiments, the dielectric material layers may be flexible and suitable for deformation. The reflective surface 105 may generally be used to reflect light, absorb light, and/or redirect light at varying angles depending on the shape of at least a portion of the shape memory alloy optical element 100 when altered by one or more of the 2-way shape memory portions 110, as will be discussed in greater detail herein.

In various embodiments, each of the 2-way shape memory portions 110 may be a region that includes a 2-way shape memory alloy (TWSMA). A TWSMA may generally be an alloy that expands and contracts between two hysteresis points depending on the temperature of the alloy. Thus, heating and/or cooling the TWSMA may cause distortion of the shape of the shape memory alloy optical element 100 in a manner that alters one or more angles of reflectance of the reflective surface 105, as will be discussed in greater detail herein. Examples of 2-way shape memory alloys may include alloy compositions such as, but not limited to, nickel-copper-niobium, nickel-titanium, copper-aluminum-nickel, indium-titanium, copper-zinc-silicon, copper-zinc-tin, copper-zinc-aluminum and/or the like.

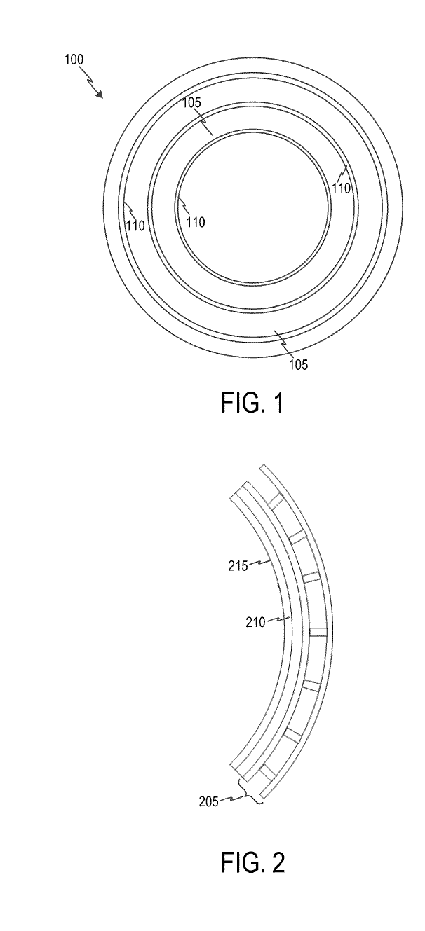

FIG. 2 depicts a cross sectional view of a 2-way shape memory portion 110 (FIG. 1) according to an embodiment. In various embodiments, each 2-way shape memory region may include at least a temperature adjustment element 205, a TWSMA layer 210, and a reflective surface 215. Each 2-way shape memory portion 110 (FIG. 1) may be positioned in an alternating pattern between two nominal optical shape portions, as described in greater detail herein.

In various embodiments, the temperature adjustment element 205 may be configured to provide heating and cooling to the TWSMA layer 210. In some embodiments, the temperature adjustment element 205 may be flexible so that it can bend with the TWSMA layer 210. The heating and cooling temperatures may be controlled by an external device and/or a device embedded within the temperature adjustment element 205, such as a processing device and/or the like, as described in greater detail herein. The heating and cooling temperatures may be temperatures that cause the TWSMA layer 210 to expand or contract. In some embodiments, the TWSMA layer 210 may expand when heated and contract when cooled. In alternative embodiments, the TWSMA layer 210 may contract when heated and expand when cooled. In an illustrative example, the temperature adjustment element 205 may be configured to heat the TWSMA layer 210 to a first temperature so that the TWSMA layer expands or contracts to a first programmed hysteresis point, as described in greater detail herein. In addition, the temperature adjustment element 205 may further be configured to cool the TWSMA layer 210 to a second temperature so that the TWSMA layer expands or contracts to a second programmed hysteresis point, as described in greater detail herein. In another example, the temperature adjustment element 205 may only be configured to heat the TWSMA layer 210 to a first temperature and then turn off, thereby causing the TWSMA layer to expand or contract as it cools. In yet another example, the temperature adjustment element 205 may only be configured to cool the TWSMA layer 210 to a first temperature and then turn off, thereby causing the TWSMA layer to expand or contract as it heats up. In each embodiment, the TWSMA layer 210 may have one or more bend angles that are different depending on which portions of the TWSMA layer are expanded and which portions of the TWSMA layer are contracted. The temperature adjustment element 205 is not limited in type by this disclosure, and may include any temperature adjustment element that is suitable for the purposes described herein. In some embodiments, the temperature adjustment element 205 may include a Peltier heater module, a Peltier cooler module, and/or the like.

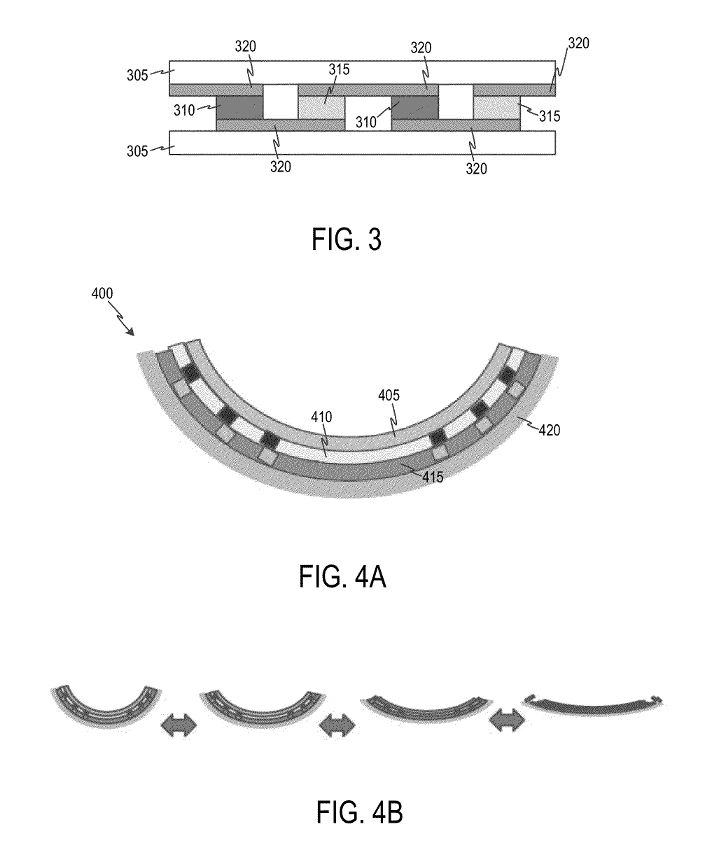

FIG. 3 depicts a detailed cross-sectional view of a temperature adjustment element 205 (FIG. 2) according to an embodiment. The temperature adjustment element may include, for example, one or more polymer film layers 305, one or more p-type semiconductors 310, one or more n-type semiconductors 315, and/or a plurality of electrodes 320. In some embodiments, the one or more polymer film layers 305 may sandwich the other components. In some embodiments, the components may each be substantially in contact with at least one of the other components. In some embodiments, the plurality of electrodes 320 may be positioned between a polymer film layer 305 and one or more of the semiconductors 310, 315.

In various embodiments, the one or more polymer film layers 305 may include a polymer thin film. In some embodiments, the polymer thin film may be a polymer film having heat resistance properties. Polymer thin films may include, but are not limited to, one or more of polyimide, polyether ether ketone (PEEK), polytetrafluoroethylene (PTFE) and polyphenylene sulfide (PPS). In some embodiments where the temperature adjustment element 205 (FIG. 2) uses more than one polymer film layer 305, the polymer film layers may be positioned so that the other components discussed herein are located between polymer film layers.

In some embodiments, the p-type semiconductor 310 may generally include a doped semiconductor that contains a larger number of holes than electrons, which increases the hole carrier concentration (p₀) of the semiconductor. In some embodiments, the n-type semiconductor 315 may generally include a doped semiconductor that contains a larger number of electrons than holes, causing the electrons to be the majority carriers. In some embodiments, the p-type semiconductor 310 may be constructed from Sb_{1.7}Bi_{0.3}Te₃ (antimony telluride with a bismuth substitution at 15% of antimony locations), CoSb₃ (cobalt triantimonide), MnSi_{1.73} (manganese silicide), and/or the like. In some embodiments, the n-type semiconductor 315 may be constructed from one or more of Bi₂Te₃ (bismuth telluride), CeSb_{2.85}Te_{0.15} (cerium antimonide with a 5% substitution of tellurium for antimony), Mg₂Si (magnesium silicide), and/or the like. In other embodiments, the semiconductors 310, 315 may be organic and/or inorganic semiconductors. Suitable inorganic semiconductors may include, for example, one or more of silicon, silicon carbide, boron nitride, aluminum nitride, nickel oxide, zinc oxide, and zinc sulfide. Suitable organic semiconductors may include, for example, one or lore of poly-3-hexylthiophene, pentacene, perylene, carbon nanotubes, and C₆₀ fullerenes.

In various embodiments, the plurality of electrodes 320 may be positioned between a polymer film 305 and the semiconductors 310, 315 in such a manner that each electrode spans a surface of the p-type semiconductor 310 and a surface of the n-type semiconductor 315 so that a gap remains between the two semiconductors. In addition, each semiconductor 310, 315 may be positioned adjacent to two electrodes 320, with one electrode adjacent to a first surface and another electrode adjacent to a second surface. However, the semiconductors 310, 315 and the electrodes 320 may be positioned in such a manner so that a p-type semiconductor 310 may share one electrode with an n-type semiconductor 315, but not both electrodes.

In various embodiments, the plurality of electrodes 320 may include one or more electrically conductive materials. Examples of electrically conductive materials may include, but are not limited to, metals such as copper, silver, aluminum, nickel, gold, and stainless steel. In some embodiments, the electrodes 320 may be arranged in any configuration, including, but not limited to, straight wires, curved wires, a mesh, and/or the like.

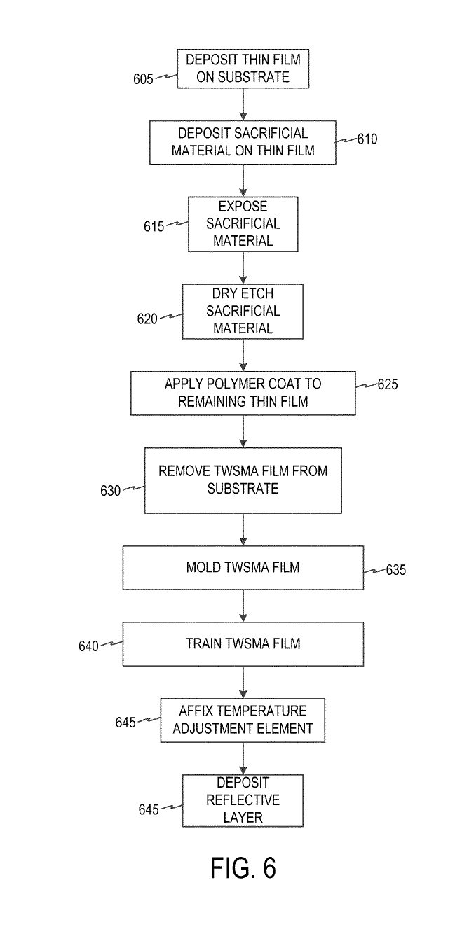

Referring back to FIG. 2, the TWSMA layer 210 may include a thin film in some embodiments. In other embodiments, the TWSMA layer 210 may include one or more TWSMA areas that are embedded within a thin film, as described in greater detail herein. In yet other embodiments, the TWSMA layer 210 may include one or more TWSMA areas that are patterned upon a surface of a thin film. In some embodiments, the TWSMA layer 210 may be disposed upon a surface of the temperature adjustment element 205. In particular embodiments, the TWSMA layer 210 may be disposed upon a surface of a polymer film layer 305 (FIG. 3) of the temperature adjustment element 205. In some embodiments, the TWSMA layer 210 may be deposited upon the temperature adjustment element 205 by any method of deposition now known or later developed, including, but not limited to, thin film deposition, photolithography, printing, molding, transferring, spinning, sputtering, and/or the like. Deposition of the TWSMA layer 210 upon the temperature adjustment element 205 will be discussed in greater detail with respect to FIGS. 6 and 8 herein.

In some embodiments, heating and/or cooling actions by the temperature adjustment element 205 at particular locations may cause the TWSMA layer 210 to expand and/or contract. The TWSMA layer 210, at each TWSMA area, may expand and/or contract between two hysteresis points in such a manner that when each area of the TWSMA layer is heated or cooled, it automatically expands and/or contracts to predetermined bend angles at that area, as described in greater detail herein. In some embodiments, each area of the TWSMA layer 210 may have a different bend angle and may respond to a different temperature to effect the bending. Thus, by controlling heating and/or cooling the plurality of areas of the TWSMA layer 210, the temperature adjustment element can cause light to reflect in specific ways depending on the bend angles of the TWSMA layers at a particular area, as well as the location of the various bend angles with respect to each other, as described in greater detail herein. In some embodiments, the plurality of areas may be configured to adjust between bend angles in concert, so as to flex and contract the entire two way shape memory portion 110 (FIG. 1) as a unit. In other embodiments, the plurality of areas may be configured to adjust between bend angles individually, so as to provide a wide range of varying bend angles and light reflection patterns on the shape memory portion 110 (FIG. 1).

As previously described herein, the reflective surface 215 may include a high reflectance material, a dielectric mirror, and/or the like. The reflective surface 215 may be deposited on the TWSMA layer 210 by any method of deposition now known or later developed, including, but not limited to, physical vapor deposition, evaporative deposition, ion beam assisted deposition, chemical vapor deposition, ion beam deposition, molecular beam epitaxy, sputter deposition, electrodeposition, and the like.

FIG. 4A depicts a cross-sectional view of an alternative shape memory alloy optical element, generally designated 400, according to an embodiment. The alternative shape memory alloy optical element 400 may generally include a reflective layer 405, a TWSMA layer 410, an additional layer 415, and a temperature adjustment element 420. While two layers are shown in this embodiment, those skilled in the art will recognize that a greater number of layers may also be used.

In some embodiments, the additional layer 415 may be a second TWSMA layer. In some embodiments, the first TWSMA layer 410 may be layered on top of the second TWSMA layer 415. In some embodiments, the TWSMA layers 410, 415 may be positioned between the reflective layer 405 and the temperature adjustment element 420. Each of the first TWSMA layer 410 and the second TWSMA layer 415 may have a plurality of areas with varying bend angles that respond to varying temperatures. Thus, in some embodiments, the additional TWSMA layers may allow for greater flexibility in providing varying bend angles at varying temperatures. In other embodiments, the additional TWSMA layers may allow for a greater overall bend angle to be achieved that would not otherwise be possible with a single TWSMA layer, as shown in FIG. 4B.

In some embodiments, the additional layer 415 may be a bimetal layer. In some embodiments, the bimetal layer may include two or more materials, where each material may have a different thermal expansion rate. Examples of suitable bimetal layers may include, for example, one or more of Fe-36Ni (“invar”)/NiMn-Steel, Fe-36Ni/MnNiCu, 38/7 NiCr-Steel/19/7 NiCr-Steel, and/or the like. In some embodiments, the bimetal layer may allow for focus switching and/or focus adjustment because each layer of the bimetal has a deformation property that is different from the other layers, causing each layer to deform at a different temperature. Thus, each layer may have a different thermal expansion rate. As a result, by controlling the temperature, the deformation of the bimetal layer may be adjusted accordingly. Thus, by combining one or more TWSMA layers 410 with a bimetal layer 415, focus switching and focus adjustment may be achieved.

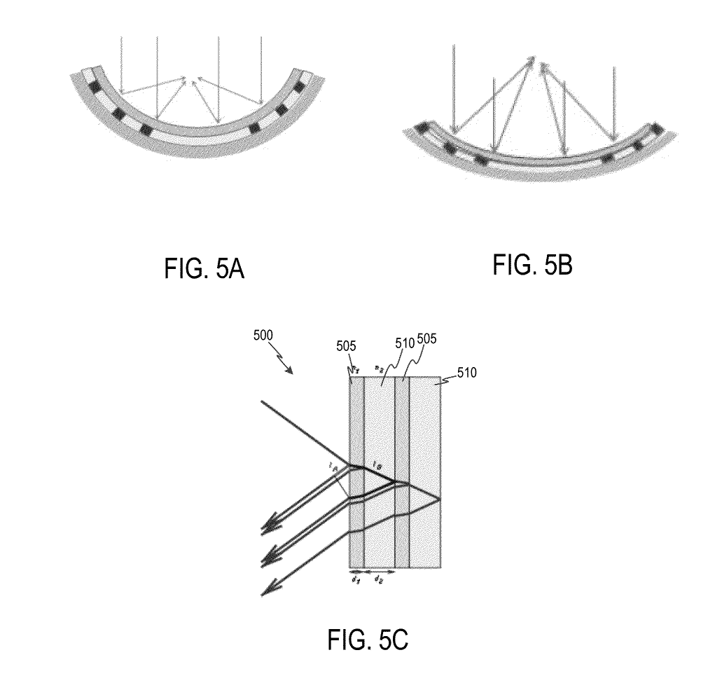

FIGS. 5A, 5B, and 5C depict schematic diagrams of operating various shape memory alloy optical elements in operation according to various embodiments. FIG. 5A depicts a shape memory alloy optical element in a first (a “hot”) state, and FIG. 5B depicts the same shape memory alloy optical element in a second (a “cold”) state. In this embodiment, all of the areas of the TWSMA may act in concert to bend to the same bend angle to provide a uniform shape, as previously described herein. Thus, as shown in FIG. 5A, when the temperature adjustment element heats the TWSMA to the first temperature, the TWSMA may contract to the bend angle associated with the first state. Similarly, as shown in FIG. 5B, when the temperature adjustment element cools the TWSMA to the second temperature, the TWSMA may expand to the bend angle associated with the second state.

As previously described herein, in some embodiments such as the one shown in FIG. 5C, the reflective layer may have a dielectric mirror 500. The dielectric mirror 500 may include a plurality of thin layers 505 and/or a plurality of thick layers 510. In some embodiments, the plurality of thin layers 505 may have a high refractive index. In some embodiments, the plurality of thick layers 510 may have a low refractive index. In some embodiments, each of the plurality of thin layers 505 may be composed of a first dielectric material. In some embodiments, each of the plurality of thick layers 510 may be composed of a second dielectric material. Examples of dielectric material may include magnesium fluoride, silicon dioxide, tantalum pentoxide, zinc sulfide, titanium dioxide, and/or the like. By providing a plurality of thin layers 505 and a plurality of thick layers 510, all with varying types of dielectric material, the manner in which light is reflected may vary based upon the wavelength, which allows for a greater number of possibilities in reflecting light in addition to the systems and methods described herein.

FIG. 6 depicts a flow diagram of a method of forming the shape memory optical alloy according to an embodiment. In some embodiments, the method may be completed manually. In other embodiments, the method may be performed by one or more machines and/or devices configured to complete at least a portion of the processes described herein. For purposes of simplicity, all of the processes described herein will be described as being completed by a system.

In various embodiments, the system may deposit 605 a thin film on a substrate. The thin film may include a 2-way shape memory alloy, as previously described herein. The substrate may be any suitable substrate for thin film deposition. Examples of suitable substrates may include, for example, glass-based or silicon-based wafers. The system may deposit 605 the thin film using any method of deposition now known or later developed, including, but not limited to, chemical vapor deposition, physical vapor deposition, electrodeposition, and/or the like.

In various embodiments, the system may deposit 610 one or more layers of sacrificial material on the thin film. In some embodiments, the one or more layers of sacrificial material may include a polymeric material that can be removed and/or etched using a method that allows for removal of at least a portion of the sacrificial material. For example, the sacrificial material may be one or more layers of electron beam (“e-beam”) resist material. The e-beam resist material may generally be a polymer material that can be altered by electron beams. Examples of e-beam resist materials include, but are not limited to, PHS polymers, PMMA polymers, novolac polymers, thiol-ene polymers, and other suitable polymers or combinations thereof. In some embodiments, the one or more layers of sacrificial material may include a first layer that has an e-beam resist material and a second layer that has a dielectric material. Examples of dielectric material include, but are not limited to, hafnium oxide, hafnium silicate, zirconium oxide, zirconium silicate, lanthanum oxide, lanthanum silicate, tantalum oxide, tantalum silicate, titanium oxide, titanium silicate, aluminum oxide, aluminum silicate, silicon oxide, derivatives thereof, or combinations thereof. Depositing 610 the sacrificial materials may be completed via, for example, spin coating, spray coating, dip coating, sputtering, flush coating, flow coating, conventional chemical vapor deposition (CVD), low pressure chemical vapor deposition (LPCVD), atomic layer deposition (ALD), pulsed chemical vapor deposition (P-CVD), plasma enhanced atomic layer deposition (PE-ALD), molecular beam epitaxy (MBE), and electron-beam metal deposition (EBMD).

In various embodiments, the method may include removing portions of the sacrificial material and/or the thin film. The step of removing may be carried out in various ways. For example, removing can be carried out by first exposing 615 portions of the sacrificial material and/or the thin film to an electron beam. Exposing may be completed using a photomask having a plurality of windows, where each window has a shape corresponding to a desired structure. For example, if a square structure is desired, the window may be a square shape. Similarly, if a triangular structure is desired, the window may be triangular. In another example, if a circular structure is desired, the window may be circular. In some embodiments, the sacrificial material and/or the thin film may be exposed to any combination of window shapes. In other embodiments, the sacrificial material and/or the thin film may be exposed to a plurality of the same window shape. In some embodiments, the sacrificial material and/or the thin film may be exposed to a plurality of windows of the same size. In other embodiments, the sacrificial material and/or the thin film may be exposed to a plurality of windows having a plurality of different sizes.

In various embodiments, the system may dry etch 620 the remaining sacrificial material and/or the thin film. The dry etching 620 may selectively remove additional portions of the remaining exposed layers to achieve specific shapes that cannot be removed via electron beam exposure. The dry etching 620 may generally use ion-based etchants. Examples of ion-based etchants may include, for example, a plasma of reactive gases such as fluorocarbons, oxygen, chlorine, boron trichloride, nitrogen, argon, helium, and/or the like. The dry etching 620 may be completed directionally and/or anisotropically.

In various embodiments, the system may apply 625 a polymer coat to the remaining thin film. In some embodiments, the polymer coat may be casted on the wafer with the patterned TWSMA areas. The patterned TWSMA areas may subsequently be buried under the polymer film. In some embodiments, the polymer coat may be a thermal resistant polymer so that the polymer is not affected by the change in temperature caused by the temperature adjustment elements. Examples of thermal resistant polymers may include, but are not limited to, polyether ether ketone, polytetrafluoroethylene, polyphenylensulfide, polyether imide, polyethersulfone, polyvinylidene diflouride (PVDF) or other fluoro polymers, polyamide, polyamide imide, polyether imide, polysulfone, liquid crystal polymer (LCP), polybenzimidazole (PBI), phenol resins, epoxy resins, silicone resins, and/or the like. The resulting TSWMA film may be used in a two-way shape memory alloy optical element.

In various embodiments, the system may remove 630 the TWSMA film containing the etched material, the polymer coat, and/or any remaining sacrificial material from the substrate to obtain a material that can be molded and heat trained. The system may mold 635 and train 640 the TWSMA film once it has been removed 630 from the substrate. Molding 635 the TWSMA film may include forming the polymer compound into a curved shape. Training 640 the TWSMA film may include using heat to cause the TWSMA film to bend to a specific angle.

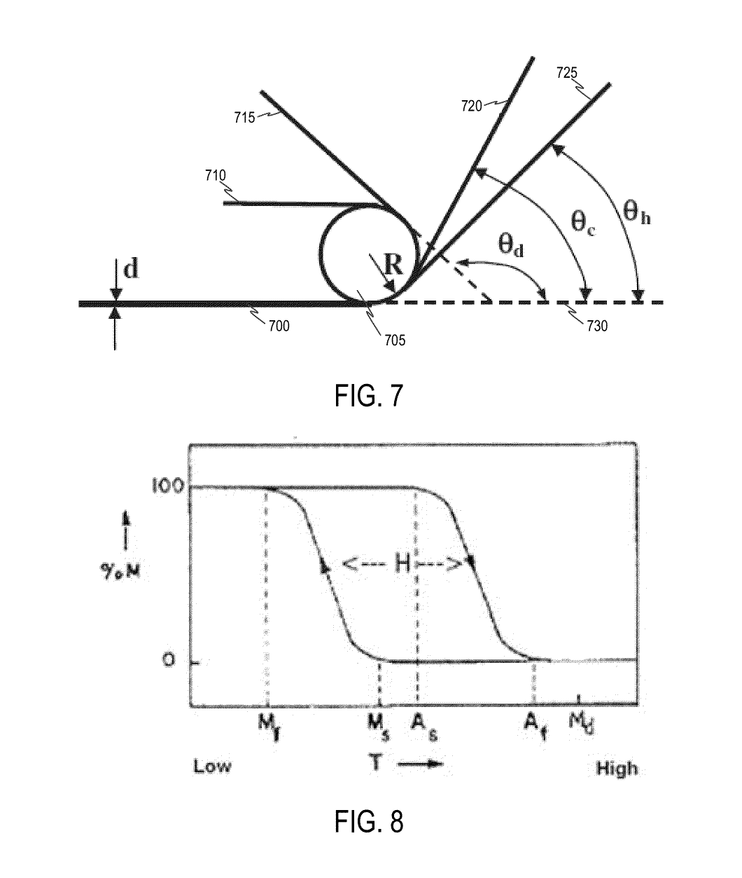

In various embodiments, molding 635 of the polymer thin film combination may be completed at substantially the same time as training 640 the polymer thin film combination. In some embodiments, the molding 635 and training 640 operations may generally be completed by repeating a plurality of steps. A first step, as shown in FIG. 7, may include bending the TWSMA film 700 against a cylindrical rod 705 to a deformation position 710 at a required temperature. The deformation position may generally be a position that is sufficient to effect shape memory training. A sufficient position may be determined, for example, by conducting advanced testing prior to completion of the steps described herein. In the present example, the deformation position may be a position that is substantially parallel to the flat portion of the TWSMA film 700. The required temperature may be, for example, a temperature that is lower than a transportation temperature Mf, as depicted in FIG. 8. In some embodiments, the required temperature may be dependent upon the type of material used in the TWSMA film 700. In some embodiments, the required temperature may be about 150 K to about 500 K. In some embodiments, the required temperature may be about 150 K, about 200 K, about 250 K, about 300 K, about 350 K, about 400 K, about 450 K, or about 500 K.

A second step may include releasing the TWSMA film to allow it to revert back to a spring back position 710. A third step may include heating the TWSMA film to a temperature up to about 600 K to recover a heating position 725. In some embodiments, the temperature may vary based on the composition of the TWSMA film. Examples of suitable temperatures may include, for example, 100 K, 200 K, 300 K, 400 K, 500 K, 600 K, and ranges between any two of these values. A fourth step may include either actively cooling the TWSMA film or allowing the TWSMA film to cool to about room temperature, which may cause the TWSMA film to move to a cooling position 720. Returning to FIG. 6, the TWSMA may be trained 640 by repeating at least the above-listed steps one or more times. A bending deformation strain may be estimated by the equation ∈_{d}=(d+2R), where ∈_{d} represents the bending deformation strain, d represents the thickness of the TWSMA film, and R is the radius of the cylindrical rod 705 (FIG. 7). A two way shape memory strain may be measured by the equation

$${ɛ}_{tw} = ( {θ}_{c} - {θ}_{h} ) \times \frac{{ɛ}_{d}}{180 °} ,$$

where ∈_{tw} represents the two way shape memory strain, θ_{c} represents the angle of the TWSMA film when it is in the cooling position 720 (FIG. 7), and θₕ represents the angle of the TWSMA film when it is in the heating position 725 (FIG. 7).

In various embodiments, the system may affix 645 the temperature adjustment element to a first surface of the TWSMA film. The temperature adjustment element may be affixed 645 by any method of affixing now known or later developed. In some embodiments, the temperature adjustment element may be affixed 645 by stacking the temperature adjustment element to the TWSMA film. In other embodiments, the temperature adjustment element may be affixed 645 with the use of adhesives, or may be affixed by blazing, welding, pressure bonding, plasma activated bonding and/or the like.

In various embodiments, the system may deposit 650 the reflective layer upon a second surface of the TWSMA film. The system may deposit 650 the reflective layer using any method of deposition now known or later developed. Illustrative deposition methods may include, but are not limited to, physical vapor deposition, evaporative deposition, ion beam assisted deposition, chemical vapor deposition, ion beam deposition, molecular beam epitaxy, sputter deposition, electroplating. and/or the like.

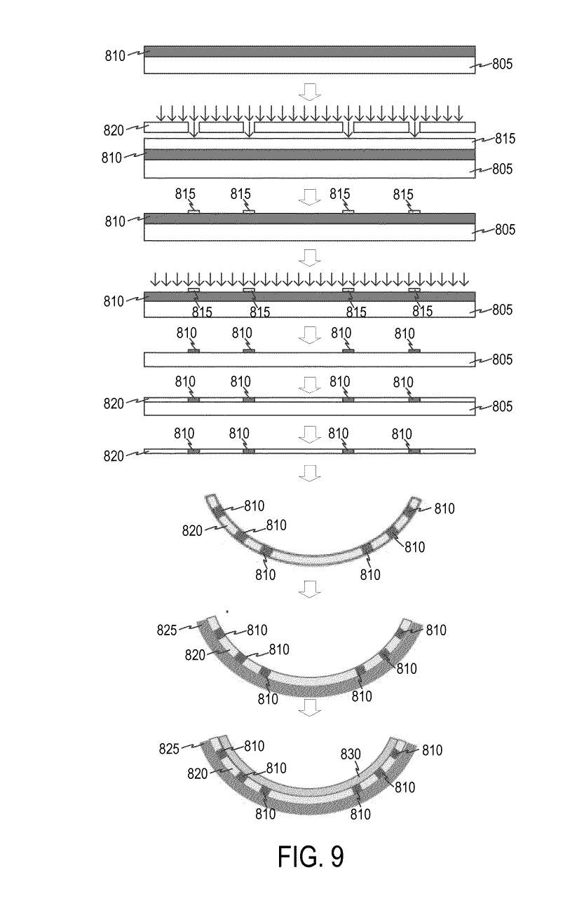

FIG. 9 depicts a schematic diagram of the method depicted in FIG. 6, according to an embodiment. In various embodiments, a thin film 810 may be deposited on a substrate 805. Sacrificial material 815 may be placed on the thin film 810, and exposed to a plurality of electron beams through a photomask 820. As a result, portions of the sacrificial material 815 may be removed. A dry etching process may remove the remaining sacrificial material 815 and portions of the thin film 810. A polymer coat 820 may be applied to the remaining portions of the thin film 810. The combination polymer coat 820 and thin film 810 may be removed from the substrate 805 for molding and heat treatment, and then may have a temperature adjustment element 825 affixed to a first surface. A reflective layer 830 may be deposited on a second surface of the combination polymer coat 820 and thin film 810.

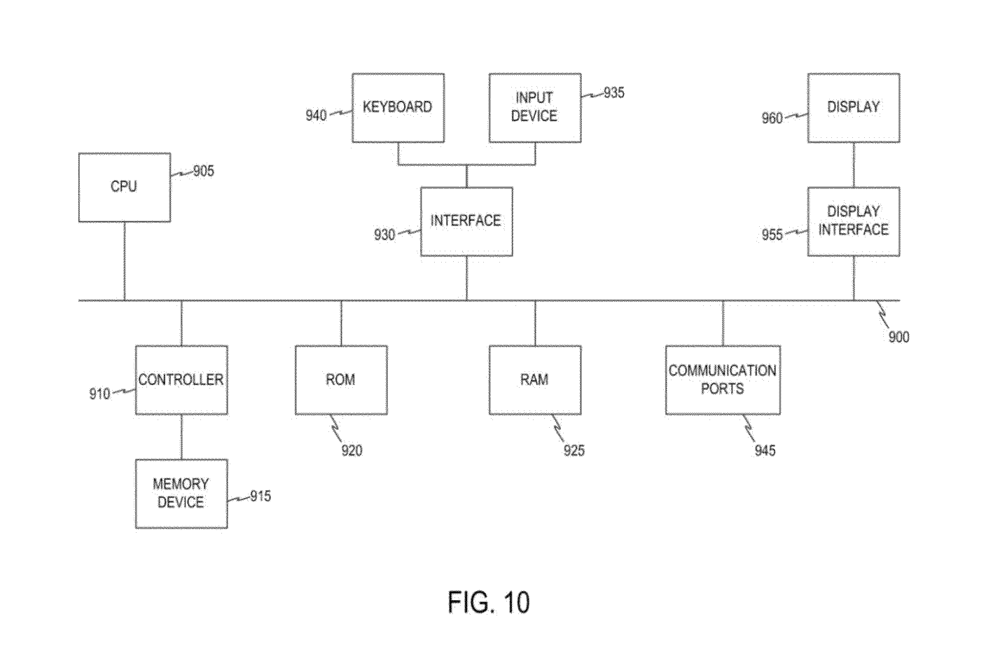

FIG. 10 depicts a block diagram of illustrative internal hardware that may be used to contain or implement program instructions according to embodiments. A bus 900 may serve as the main information highway interconnecting the other illustrated components of the hardware. A CPU 905 may be the central processing unit of the system, performing calculations and logic operations required to execute a program. The CPU 905, alone or in conjunction with one or more of the other elements disclosed herein, is an illustrative processing device, computing device or processor as such terms are used within this disclosure. Read only memory (ROM) 920 and random access memory (RAM) 925 constitute illustrative memory devices (for example, processor-readable non-transitory storage media).

A controller 910 interfaces with one or more optional memory devices 915 to the system bus 900. These memory devices 915 may include, for example, an external or internal DVD drive, a CD ROM drive, a hard drive, flash memory, a USB drive or the like. As indicated previously, these various drives and controllers are optional devices.

Program instructions, software or interactive modules for providing the interface and performing any querying or analysis associated with one or more data sets may be stored in the ROM 920 and/or the RAM 925. Optionally, the program instructions may be stored on a tangible computer readable medium such as a compact disk, a digital disk, flash memory, a memory card, a USB drive, an optical disc storage medium, such as a Blu-Ray™ disc, and/or other non-transitory storage media.

An optional display interface 955 may permit information from the bus 900 to be displayed on the display 960 in audio, visual, graphic or alphanumeric format. Communication with external devices, such as a print device, may occur using various communication ports 945. An illustrative communication port 945 may be attached to a communications network, such as the Internet or an intranet.

The hardware may also include an interface 930 which allows for receipt of data from input devices such as a keyboard 940 or other input device 935 such as a mouse, a joystick, a touch screen, a remote control, a pointing device, a video input device and/or an audio input device.

The various embodiments may be realized in the specific examples found below.

### EXAMPLES

### Example 1

### Binoculars

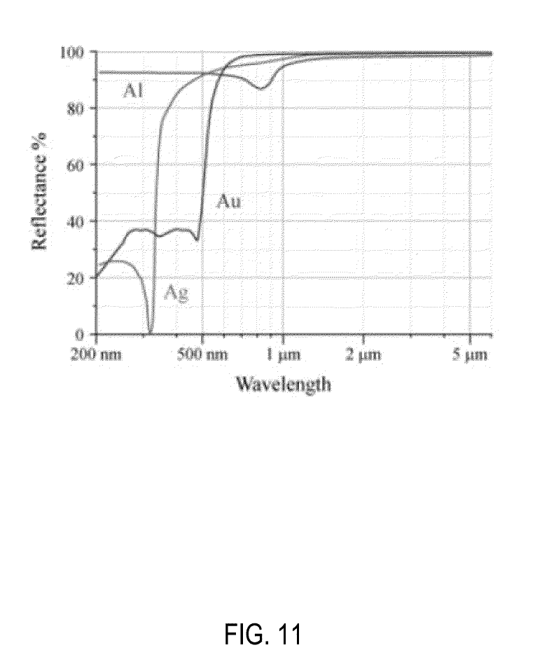

A shape memory alloy apparatus will be used for a child's binocular toy to allow two focus presets: “close-up” (5-10 meters) and “distance” (greater than 10 meters). The shape memory apparatus will be formed with a single TWSMA layer, an aluminum reflective layer and a Peltier module. The aluminum layer will allow for a high reflectance over a wide variety of wavelengths, as shown in the graphical illustration in FIG. 11. The single TWSMA layer will have a plurality of areas that have been molded and are embedded in a thermally resistant film. The TWSMA layer will further be configured so that each of the areas work in unison to expand and contract the shape memory alloy apparatus to one of two shapes. The Peltier module will be configured for both heating and cooling purposes. Specifically, the Peltier module will heat the TWSMA layer to about 350 K, causing shape memory alloy apparatus to contract to a first position when the “close-up” mode is selected by a user. In addition, the Peltier module will cool the TWSMA layer to about 300 K, causing the shape memory alloy apparatus to expand to a second position when the “distance” mode is selected by the user. The heating and cooling process will be completed rapidly so that the shape memory alloy apparatus contracts and expands substantially immediately after the “distance” and “close-up” modes are selected by the user.

### Example 2

### Head Mounted Display Device

A head mounted display (HMD) device used for an augmented reality gaming system will include two small displays positioned at a location where, when the HMD is worn by a user, the two small displays are positioned directly in front of the user's eyes. To give the user a perception of a real-life environment and to provide a three dimensional field of view (FOV), the HMD will incorporate a plurality of lenses. Given that it is desirable for the HMD to be as small as possible to allow the wearer to be comfortable and have full physical motion, the somewhat bulky traditional lens is less desirable. Accordingly, one or more shape memory alloy apparatuses will be used. The shape memory alloy apparatuses will each have 3 layers of TWSMA material embedded in heat-resistant polymer film, where the layers are stacked atop each other. Each layer of TWSMA material will have 10 heat molded areas, each of which is configured to expand and contract at a different specific angle. Thus, 30 areas will exist in the shape memory alloy apparatus, each of which is specifically positioned at a location and configured to expand and contract at a different angle so that a large number of angles of light reflectance can be achieved. A reflective layer comprised of a dielectric mirror will be affixed to a top layer of the 3 stacked TWSMA layers. The dielectric mirror will be connected to a processor that is controlled with programming instructions to direct the dielectric mirror to reflect varying wavelengths at varying angles. A Peltier module will be affixed to a bottom layer of the 3 stacked TWSMA layers. The Peltier module will be configured to provide heating and cooling to each of the 30 areas individually. Thus, the Peltier module will be able to provide varying heating and cooling stimulations to each of the 30 areas individually. The Peltier module will also be connected to the processor, which will also be controlled with programming instructions to direct the Peltier module to heat or cool each of the 30 areas in a manner to constantly change how light is reflected off of each shape memory alloy apparatus so that the light is reflected to the user's eyes in a manner that gives the perception of a virtual reality simulation.

### Example 3

### Manufacturing Process

A large scale manufacturing process will allow for an economical way to make the various components of a shape memory alloy apparatus. The large scale manufacturing process will include taking very large sheets of glass substrate, such as sheets that are about 5 meters by 10 meters in size, and depositing a thin film on the substrate using a thin film deposition method. The manufacturing process will include depositing a layer of sacrificial material onto the thin film via a similar deposition method, and etching a plurality of two way shape memory areas into the thin film via a photolithographic method. Once the pattern has been etched, the manufacturing process will include applying a heat resistant polymer coat to the pattern and removing the resulting material from the glass substrate via a peeling process.

The manufacturing process will include rolling the resulting material around a cylindrical object and training the material to expand and contract when heating and cooling is applied to it. The rolling process will be completed a minimum of 5 times to ensure proper heat training Once the material has been trained, the manufacturing process will include laying the material out flat on a surface and cutting it into smaller pieces, where the size of the pieces depends upon the application.

The manufacturing process will optionally include arranging the cut smaller pieces depending on the application, such as stacking a plurality of pieces together and affixing them with an adhesive. The manufacturing process will include depositing a reflective coating on one surface of the cut smaller pieces and affixing a Peltier module to another surface of the cut smaller pieces.

The manufacturing process will include programming each Peltier module to heat and/or cool to a specific temperature, depending on the application. Alternatively, the manufacturing process will include affixing a processor and a memory to the Peltier module, where the memory contains programming instructions for adjusting the heating and cooling on the Peltier module, to be carried out by the processor.

In the above detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be used, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, compositions or biological systems, which can, of course, vary. It is also to be understood that the terminology used herein is for the purpose of describing particular embodiments only, and is not intended to be limiting.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (for example, bodies of the appended claims) are generally intended as “open” terms (for example, the term “including” should be interpreted as “including but not limited to,” the term “having” should be interpreted as “having at least,” the term “includes” should be interpreted as “includes but is not limited to,” et cetera). While various compositions, methods, and devices are described in terms of “comprising” various components or steps (interpreted as meaning “including, but not limited to”), the compositions, methods, and devices can also “consist essentially of” or “consist of” the various components and steps, and such terminology should be interpreted as defining essentially closed-member groups. It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (for example, “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (for example), the bare recitation of “two recitations,” without other modifiers, means at least two recitations, or two or more recitations). Furthermore, in those instances where a convention analogous to “at least one of A, B, and C, et cetera” is used, in general such a construction is intended in the sense one having skill in the art would understand the convention (for example, “a system having at least one of A, B, and C” would include but not be limited to systems that have A alone, B alone, C alone, A and B together, A and C together, B and C together, and/or A, B, and C together, et cetera). In those instances where a convention analogous to “at least one of A, B, or C, et cetera” is used, in general such a construction is intended in the sense one having skill in the art would understand the convention (for example, “a system having at least one of A, B, or C” would include but not be limited to systems that have A alone, B alone, C alone, A and B together, A and C together, B and C together, and/or A, B, and C together, et cetera). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, et cetera As a non-limiting example, each range discussed herein can be readily broken down into a lower third, middle third and upper third, et cetera As will also be understood by one skilled in the art all language such as “up to,” “at least,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

Various of the above-disclosed and other features and functions, or alternatives thereof, may be combined into many other different systems or applications. Various presently unforeseen or unanticipated alternatives, modifications, variations or improvements therein may be subsequently made by those skilled in the art, each of which is also intended to be encompassed by the disclosed embodiments.

1. An optical component comprising:
a plurality of patterned two-way shape memory alloy portions, wherein each patterned two-way shape memory alloy portion comprises a reflective surface and a temperature adjustment element, wherein each patterned two-way shape memory alloy portion is individually configured to flex to a first bend angle at a first temperature and a second bend angle at a second temperature; and
a plurality of nominal optical shape portions positioned between the plurality of patterned two-way shape memory alloy portions.

2. (canceled)

3. (canceled)

4. The optical component of claim 1, wherein the patterned two-way shape memory alloy portions each comprise an alloy selected from nickel-copper-niobium, nickel-titanium, copper-aluminum-nickel, indium-titanium, copper-zinc-silicon, copper-zinc-tin, and copper-zinc-aluminum.

5. The optical component of claim 1, wherein the reflective surface comprises at least one of chromium, silver, aluminum, and gold.

6. The optical component of claim 1, wherein the reflective surface comprises a dielectric mirror having a plurality of dielectric material layers, wherein the dielectric mirror comprises at least one of magnesium fluoride, silicon dioxide, tantalum pentoxide, zinc sulfide, and titanium dioxide.

7. (canceled)

8. The optical component of claim 1, wherein the temperature adjustment element comprises at least one of:
a Peltier module;
a polymer thin film comprising one or more of polyimide, polyether ether ketone, polytetrafluoroethylene, and polyphenylene sulfide; and
a semiconductor material comprising at least one of Bi₂Te₃, CeSb_{2.85}Te_{0.15}, Mg₂Si, Bi_{0.3}Sb_{1.7}Te₃, CoSb₃, and MnSi_{1.73}.

9.-12. (canceled)

13. The optical component of claim 1, wherein a first group of the patterned two-way shape memory alloy portions is layered over a second group of the patterned two-way shape memory alloy portions.

14. The optical component of claim 1, further comprising a bimetal structure.

15. An article of manufacture comprising an optical component, wherein the optical component comprises:
a plurality of patterned two-way shape memory alloy portions, wherein:
each patterned two-way shape memory alloy portion comprises a reflective surface and a temperature adjustment element, and
each patterned two-way shape memory alloy portion is individually configured to flex to a first bend angle at a first temperature and a second bend angle at a second temperature; and
a plurality of nominal optical shape portions positioned between the plurality of patterned two-way shape memory alloy portions.

16. (canceled)

17. (canceled)

18. The article of manufacture of claim 15, wherein the patterned two-way shape memory alloy portions each comprise an alloy selected from nickel-copper-niobium, nickel-titanium, copper-aluminum-nickel, indium-titanium, copper-zinc-silicon, copper-zinc-tin and copper-zinc-aluminum.

19. The article of manufacture of claim 15, wherein the reflective surface comprises at least one of chromium, silver, aluminum, and gold.

20. The article of manufacture of claim 15, wherein the reflective surface comprises a dielectric mirror having a plurality of dielectric material layers, wherein the dielectric mirror comprises at least one of magnesium fluoride, silicon dioxide, tantalum pentoxide, zinc sulfide, and titanium dioxide.

21. (canceled)

22. The article of manufacture of claim 15, wherein the temperature adjustment element comprises at least one of:
a Peltier module;
a polymer thin film comprising one or more of polyimide, polyether ether ketone, polytetrafluoroethylene, and polyphenylene sulfide; and
a semiconductor material comprising at least one of Bi₂Te₃, CeSb_{2.85}Te_{0.15}, Mg₂Si, Bi_{0.3}Sb_{1.7}Te₃, CoSb₃, and MnSi_{1.73}.

23.-26. (canceled)

27. The article of manufacture of claim 15, wherein a first group of the patterned two-way shape memory alloy portions is layered over a second group of the patterned two-way shape memory alloy portions.

28. The article of manufacture of claim 15, further comprising a bimetal structure.

29. The article of manufacture of claim 15, wherein the article of manufacture is an optical system, a head-mounted display, a camera, a camera lens, a barcode scanner, an optical scanner, a telescope, a microscope, a pair of binoculars, a thermal imaging device, a flashlight, a magnifying glass, aeronautical equipment, automotive equipment, a contact lens, an intracapsular implant device, eyeglasses, sunglasses, a lighthouse, a computer peripheral, a projector, and an optical disc drive.

30. A method of forming an optical element, the method comprising:
forming a two-way shape memory alloy pattern on a substrate;
forming a plurality of nominal shape portions within the two-way shape memory alloy pattern;
applying a polymer solution to the two-way shape memory alloy pattern and the plurality of nominal shape portions to obtain a polymer film;
removing the polymer film from the substrate to obtain a polymer compound comprising the polymer solution, the two-way shape memory alloy pattern and the plurality of nominal shape portions;
molding the polymer compound;
depositing a reflective layer upon a surface of the polymer compound; and
affixing a temperature adjustment element to the polymer compound.

31. The method of claim 30, wherein forming the two-way shape memory alloy pattern comprises forming a pattern using at least one alloy selected from nickel-copper-niobium, nickel-titanium, copper-aluminum-nickel, indium-titanium, copper-zinc-silicon, copper-zinc-tin, and copper-zinc-aluminum.

32. The method of claim 30, wherein forming the two-way shape memory alloy pattern comprises forming the two-way shape memory alloy pattern by one or more of:
thin film deposition;
photolithography;
printing;
transferring; and
molding.

33. The method of claim 32, wherein forming the two-way shape memory alloy pattern by thin film deposition comprises forming the two-way shape memory alloy pattern by one or more of physical vapor deposition, evaporative deposition, ion beam-assisted deposition, chemical vapor deposition, ion beam deposition, molecular beam epitaxy, sputter deposition, and electrodeposition.

34. The method of claim 30, wherein molding the polymer compound comprises forming the polymer compound into a curved shape, wherein the polymer compound is configured to flex at a first bend angle at a first temperature and a second bend angle at a second temperature.

35. The method of claim 30, wherein depositing the reflective layer comprises depositing at least one of chromium, silver, aluminum, and gold.

36. The method of claim 30, wherein depositing the reflective layer comprises one or more of physical vapor deposition, evaporative deposition, ion beam-assisted deposition, chemical vapor deposition, ion beam deposition, molecular beam epitaxy, sputter deposition, and electroplating.

37. The method of claim 30, wherein depositing the reflective layer comprises depositing one or more layers of a dielectric mirror, wherein the one or more layers of the dielectric mirror comprise at least one of magnesium fluoride, silicon dioxide, tantalum pentoxide, zinc sulfide, and titanium dioxide.

38. (canceled)

39. The method of claim 30, wherein affixing the temperature adjustment element comprises affixing at least one of:
a planar-type Peltier module affixed to a second polymer film, wherein the second polymer film comprises one or more of polyimide, polyether ether ketone, polytetrafluoroethylene, and polyphenylene sulfide; and
a semiconductor material, wherein the semiconductor material comprises one of Bi₂Te₃, CeSb_{2.85}Te_{0.15}, Mg₂Si, Bi_{0.3}Sb_{1.7}Te₃, CoSb₃, and MnSi_{1.73}.

40.-42. (canceled)

43. The method of claim 30, further comprising depositing a second polymer compound upon a second surface of the polymer compound.

44. The method of claim 30 further comprising combining the two-way shape memory alloy pattern with a bimetal structure.

45.-51. (canceled)
